(19) United States
(12) Patent Application Publication
(10) Pub. No.: US 2009/0189170 A1
(43) Pub. Date: Jul. 30, 2009

(54) Light emitting diode

(76) Inventors: Chung-Chan Wu, Taipei City (TW); Chia-Hao Wu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/076,369

(22) Filed: Mar. 18, 2008

(30) Foreign Application Priority Data
Jan. 30, 2008 (CN) 200810005310.7

(51) Int. Cl. H01L 33/00

(52) U.S. Cl. 257/98; 257/E33.001

(57) ABSTRACT

A light emitting diode includes a casing, comprising a concave accommodation space; a lead frame, disposed in the casing, wherein the lead frame has at least two individual leads which extend into the accommodation space; a light emitting chip, disposed in the accommodation space and electrically connected to the leads; and an encapsulating material, inside the accommodation space. The light emitting diode emits light along an optical axis. The ratio of a first tilt angle between the first reflecting wall and the optical axis, and a second tilt angle to a second tilt angle between the second reflecting wall and the optical axis is no more than 4.

### BACKGROUND OF THE INVENTION

1. Field of the Invention

The invention generally relates to a surface mount-type light emitting diode, especially to a light emitting diode which can be used as a light source of a backlight module with high light intensity and large emitting angle. A precise description would be “Integrated reflector cup for a light emitting device”.

2. Description of the Related Art

A conventional light emitting diode, such as in U.S. Pat. No. 6,995,402, includes a semiconductor light emitting device and a lead frame. The lead frame includes a diode body and a material layer which forms a reflective wall. The reflective wall is used to reflect the light emitted from the semiconductor light emitting device. The semiconductor light emitting device is disposed in the lead frame.

However, the reflective wall of the conventional light emitting device cannot collect all the light from the semiconductor light emitting device. Therefore, the light emitting efficiency of the conventional light emitting diode is poor and cannot offer satisfactory emitted light intensity.

Therefore, there is a need of a light emitting diode which can solve the prior art problem.

### SUMMARY OF THE INVENTION

An object of the invention is to provide a light emitting diode whose tilt angles of reflecting walls create larger emitted light intensity in both long and short axis directions. Therefore, it is suitable for backlight background.

In order to achieve the above objectives, the light emitting diode emitting light along an optical axis according to the invention includes a casing, a lead frame, a light emitting chip, an encapsulating material; wherein, the light emitting chip is the light emitting source and the light originates from it. The casing includes a concave accommodation space which includes a bottom formed by the casing. The second reflecting wall has a length smaller than the first reflecting wall. The first tilt angle is defined between the first reflecting wall and the optical axis, and a second tilt angle is defined between the second reflecting wall and the optical axis. The ratio of the first tilt angle to the second tilt angle is not more than 4.

The lead frame is disposed in the casing and has two individual leads which extend into the accommodation space. The light emitting chip and the encapsulating material are in the accommodation space of the casing. The leads of the lead frame are electrically connected to the light emitting chip.

The light emitting diode according to the invention is suitable for the backlight module due to larger emitted light intensity and angles, so as to increase uniformity of the light from the backlight module, reduce hot spots, and effectively guide the light to enter the backlight module.

To provide a further understanding of the invention, the following detailed description illustrates embodiments and examples of the invention, this detailed description being provided only for illustration of the invention.

### BRIEF DESCRIPTION OF THE DRAWINGS

FIG. 1 is a perspective of a light emitting diode according one embodiment of the invention

FIG. 2 is a front view of a light emitting diode according to one embodiment of the invention;

FIG. 3 is a cross-sectional view of FIG. 2 along line 3-3; and

FIG. 4 is a cross-sectional view of FIG. 2 along line 4-4.

### DETAILED DESCRIPTION OF THE EMBODIMENTS

Wherever possible in the following description, like reference numerals will refer to like elements and parts unless otherwise illustrated.

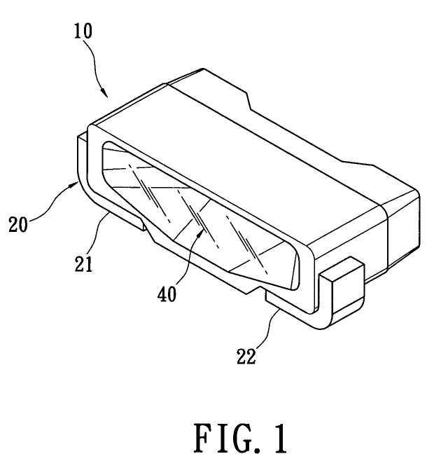

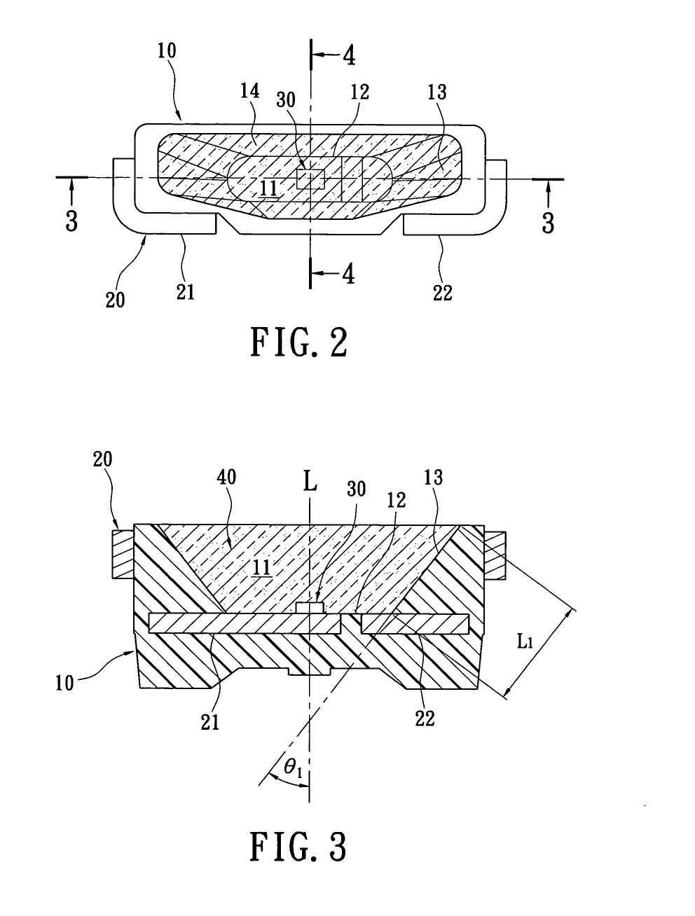

Referring to FIG. 1 through FIG. 4, a light emitting diode of the invention emits light beams along an optic axis L. In one embodiment, the light emitting diode is a surface mount-type side-look light emitting diode. The term side-look LED is employed is because the light emits from the side when the device is in its proper position, as can be seen from FIGS. 1 and 2. The light emitting diode includes a casing 10, a lead frame 20, a light emitting chip 30 and an encapsulating material 40; wherein, the light emitting chip 30 is the light emitting source and the light originates from it

The casing 10 includes a concave accommodation space 11 having a smooth inner surface. The accommodation space 11 includes a bottom 12 formed by the casing 10, a first reflecting wall 13 and a second reflecting wall 14. The first reflecting wall 13 and the second reflecting wall 14 extend downward at a tilt angle are connected to the bottom 12 from opposite sides respectively along a long axis and a short axis of the casing 10.

Light intensity tests are performed at any tilt angle related to the reflecting angle. It was found that a required emitted light intensity can be obtained based on a particular range of tilt angle related to the reflecting walls and an emitted light intensity of long axis.

An angle between the first reflecting wall 13 and the optical axis L is defined as a first tilt angleθ1, referring to FIG. 3. In this embodiment, the first tilt angle for obtaining the required emitted light intensity for the light emitting diode is in the range of 30°-60°, and preferably 35°-45°.

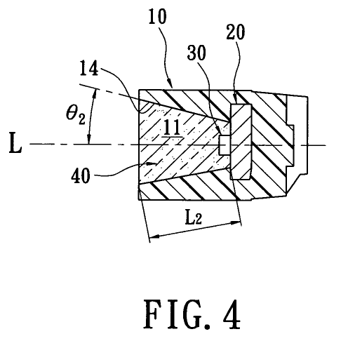

The second reflecting wall 14 has a length L2 smaller than a first length L1 of the first reflecting wall 13. Furthermore, an angle between the second reflecting wall 14 and the optical axis L is defined as a second tilt angle θ2 as shown in FIG. 4. The second tilt angleθ2 for obtaining the required emitted light intensity is in the range of 5°-25°, and preferably 8°-20°.

Furthermore, the ratio of the first tilt angleθ1 to the second tilt angleθ2 is not larger than 4. In this embodiment, the concave accommodation space 11 of the casing 10 is in the shape of concave oval with its bottom smaller than its top. The number of the first reflecting wall 13 and the second reflecting wall 14 is not particularly limited. The accommodation space 11 is defined by at least two opposite first reflecting walls 13 and at least two opposite second reflecting walls 14. The at least two first reflecting walls 13 are disposed at either sides of the bottom 12 along the long-axis direction of the casing 10. The at least two reflecting walls 14 are disposed at either sides of the bottom 12 along the short-axis direction of the casing 10.

The lead frame 20 is made of an electrically conductive metal by pressing. The lead frame 20 is disposed inside the casing 10 and has at least two individual leads 21, 22 which extend into the accommodation space 11 of the casing 10.

In this embodiment, the lead frame 20 has the first lead 21 and the second lead 22 respectively for positive and negative electrodes. However, the number of the leads is not particularly limited. Three or more leads (not shown) can be included if needed.

The light emitting chip 30 is disposed inside the accommodation space 11 of the casing 10. The light emitting chip 30 is electrically connected to the first lead 21 and the second lead 22 of the lead frame 20.

The encapsulating material 40 can be a transparent material such as epoxy or silicon. The encapsulating material 40 can be filled in the accommodation space 11 of the casing 10 to complete the encapsulating process. When a voltage is applied to the leads 21, 22, the light emitting chip 30 starts to emit light.

The encapsulating material 40 can further include fluorescent material, light scattering material or pigment, which adds colors to the light from the light emitting chip 30.

Furthermore, an inner surface of the accommodation space 11 of the casing 10 can be further covered with highly reflective metal such as silver, gold, aluminum etc by electric plating. The highly reflective metal layer of the accommodation space 11 (not shown) increases the reflection of the light emitting chip 30.

In the light emitting diode of the invention, the angle between the first reflecting wall 13 and the optical axis L is in the range of 35°-45°, and the angle between the second reflecting wall 14 and the optical axis L is in the range of 8°-20°. When the light emitting chip 30 emits the light, the above angles which is larger than the prior art allow the light reaching the first reflecting wall 13 and the second reflecting wall 14 to easily reflect out of the casing 10. Therefore, the light emitting diode can has light emitting angle of up to 120° in long-axis direction so as to increase the uniformity of the backlight module and reduce hot spots. The light emitting diode has light emitting angle of up to 95°-105° in the short-axis direction so as to effectively guiding the light to enter the backlight module. In the case of 0.8 mm thick side-look light emitting diode, the accommodation space 11 has the first reflecting wall 13 and the second reflecting wall 14, which increase the emitted light intensity by 20%.

Therefore, the light emitting diode can have light emitting chips 30 with different light emitting angles such as 115°-170°. Furthermore, the light emitting diode has larger light intensity and angle in both long and short axis directions.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A light emitting diode, comprising:
a casing, comprising a concave accommodation space
a lead frame, disposed in the casing, wherein the lead frame has at least two individual leads which extend into the accommodation space;
a light emitting chip, disposed in the accommodation space and electrically connected to the leads; and
an encapsulating material inside the accommodation space;
wherein the light emitting diode emits light along an optical axis, the accommodation space includes a bottom formed by the casing, at least two opposite first reflecting walls and at least two opposite second reflecting walls, the second reflecting wall has a length smaller than the first reflecting wall, a first tilt angle is defined between the first reflecting wall and the optical axis, and a second tilt angle is defined between the second reflecting wall and the optical axis, and the ratio of the first tilt angle to the second tilt angle is not more than 4.

2. The light emitting diode of claim 1, wherein the accommodation space has an oval shape.

3. The light emitting diode of claim 1, wherein the accommodation space further has a highly reflective layer on its inner surface.

4. The light emitting diode of claim 1, wherein the accommodation space has a smooth inner surface.

5. The light emitting diode of claim 1, wherein the encapsulating material is epoxy or silicon.

6. The light emitting diode of claim 1, wherein the encapsulating material includes fluorescent material, light scattering material or pigment.

7. The light emitting diode of claim 1, wherein the first tilt angle is in the range of 30°-60°.

8. The light emitting diode of claim 1, wherein the second tilt angle is in the range of 5°-25°.

9. The light emitting diode of claim 1, wherein the light emitting diode is side-look light emitting diode.

10. A light emitting diode, comprising:
a casing, comprising a concave accommodation space,
a lead frame, disposed in the casing, wherein the lead frame has at least two individual leads which extend into the accommodation space;
a light emitting chip, disposed in the accommodation space and electrically connected to the leads; and
an encapsulating material, inside the accommodation space;
wherein the light emitting diode emits light along an optical axis, the accommodation space includes a bottom formed by the casing, at least two opposite first reflecting walls and at least two opposite second reflecting walls, the second reflecting wall has a length smaller than the first reflecting wall, a first tilt angle is defined between the first reflecting wall ad the optical axis and is in the range of 30°-60°, and a second tilt angle is defined between the second reflecting wall and the optical axis.

11. The light emitting diode of claim 10, wherein the accommodation space has an oval shape.

12. The light emitting diode of claim 10, wherein the accommodation space further has a highly reflective layer on its inner surface.

13. The light emitting diode of claim 10, wherein the first tilt angle is in the range of 35°-45°.

14. The light emitting diode of claim 10, wherein the second tilt angle is in the range of 5°-25°.

15. A light emitting diode, comprising:
a casing, comprising a concave accommodation space
a lead frame, disposed in the casing, wherein the lead frame has at least two individual leads which extend into the accommodation space;
a light emitting chip, disposed in the accommodation space and electrically connected to the leads; and
an encapsulating material, inside the accommodation space;
wherein the light emitting diode emits light along an optical axis, the accommodation includes a bottom formed by the casing, at least two opposite first reflecting walls and at least two opposite second reflecting walls, the second reflecting wall has a length smaller than the first reflecting wall, a first tilt angle is defined between the first reflecting wall ad the optical axis, and a second tilt angle is defined between the second reflecting wall and the optical axis and is in the range of 5°-25°.

16. The light emitting diode of claim 15, wherein the accommodation space has an oval shape.

17. The light emitting diode of claim 15, wherein the accommodation space further has a highly reflective layer on its inner surface.

18. The light emitting diode of claim 15, wherein the first tilt angle is in the range of 30°-60°.

19. The light emitting diode of claim 15, wherein the second tilt angle is in the range of 8°-20°.
